(19) United States
(12) Patent Application Publication
(10) Pub. No.: US 2015/0124540 A1
(43) Pub. Date: May 7, 2015

(54) SEMICONDUCTOR INTEGRATED CIRCUIT

(71) Applicant: SK hynix Inc., Icheon-si Gyeonggi-do (KR)

(72) Inventor: Hyun Gyu LEE, Icheon-si Gyeonggi-do (KR)

(73) Assignee: SK hynix Inc., Icheon-si Gyeonggi-do (KR)

(21) Appl. No.: 14/164,897

(22) Filed: Jan. 27, 2014

(30) Foreign Application Priority Data
Nov. 1, 2013 (KR) 10-2013-0132387

(51) Int. Cl. G11C 7/22; G11C 7/12; G11C 7/06

(52) U.S. Cl. CPC G11C 7/22; G11C 7/06; G11C 7/12
USPC 365/194; 365/191

(57) ABSTRACT

A system including a circuit integrated with a semiconductor is provided. The system includes a first data line, a second data line, and a first sense amp configured to sense and amplify data of the first data line. The first sense amp is also configured to transfer the amplified data to the second data line in response to a third control signal. The system also includes a control signal generation circuit configured to generate a first control signal for controlling a precharge of the first data line and a second control signal for controlling a reset of the second data line in response to a preparatory signal and a third control signal. The third control signal is generated in response to the first control signal and the second control signal.

### CROSS-REFERENCE TO RELATED APPLICATION

The present application claims priority under 35 U.S.C. §119(a) to Korean application number 10-2013-0132387, filed on Nov. 1, 2013, in the Korean Intellectual Property Office, which is incorporated herein by reference in its entirety.

### BACKGROUND

1. Technical Field

Various embodiments relate to a semiconductor circuit, and more particularly, to a semiconductor integrated circuit.

2. Related Art

Currently known semiconductor integrated circuits, such as, for example, a semiconductor memory device, may include various circuits for data input and output and various control signals for timing control of the circuits.

For example, such a semiconductor integrated circuit as discussed above may further include a control signal for precharge and reset of a differential data line and for controlling sensing timing of sense amps coupled to a data line.

Further, a timing of the control signal as associated with such a semiconductor integrated circuit may not be punctual or may lag behind or lead a schedule according to variation of power, voltage and temperature (PVT), which may cause an unwanted error of data input or output.

### SUMMARY

Various embodiments are directed toward a semiconductor integrated circuit capable of stable data input and output.

In an embodiment, a system including a circuit integrated with a semiconductor may include a first data line, a second data line, a first sense amp configured to sense and amplify data of the first data line and transfer the amplified data to the second data line in response to a third control signal. The semiconductor integrated circuit may also include a control signal generation circuit configured to generate a first control signal for controlling precharge of the first data line and a second control signal for controlling reset of the second data line. The first and second control signals, as described here, may be generated in response to preparatory signals. Also, a third control signal may be generated in response to the first control signal and the second control signal.

In another embodiment, a semiconductor integrated circuit may include a first data line control unit configured to precharge a first data line in response to a first control signal and a second data line control unit configured to precharge a second data line in response to a second control signal. The semiconductor integrated circuit may also include a sense amp configured to sense and amplify data of the first data line and transfer the amplified data to the second data line in response to a third control signal. Also, a control signal generation circuit may be configured to generate the first control signal and the second control signal in response to preparatory signals. The preparatory signals are generated according to a read command, and the third control signal is generated in response to the first control signal and the second control signal.

### BRIEF DESCRIPTION OF THE DRAWINGS

Features, aspects and embodiments are described in conjunction with the attached drawings, in which:

FIG. 1 is a block diagram illustrating a semiconductor integrated circuit.

FIG. 2 is a block diagram illustrating a control signal generation unit of the semiconductor integrated circuit shown in FIG. 1.

FIG. 3 is a block diagram illustrating another semiconductor integrated circuit.

FIG. 4 is a block diagram illustrating a control signal generation unit of the semiconductor integrated circuit shown in FIG. 3.

FIG. 5 is a timing diagram illustrating an operation of the semiconductor integrated circuit shown in FIG. 3.

### DETAILED DESCRIPTION

Herein, a system including a circuit integrated with a semiconductor and a semiconductor integrated circuit will be described below with reference to the accompanying drawings which illustrate various embodiments.

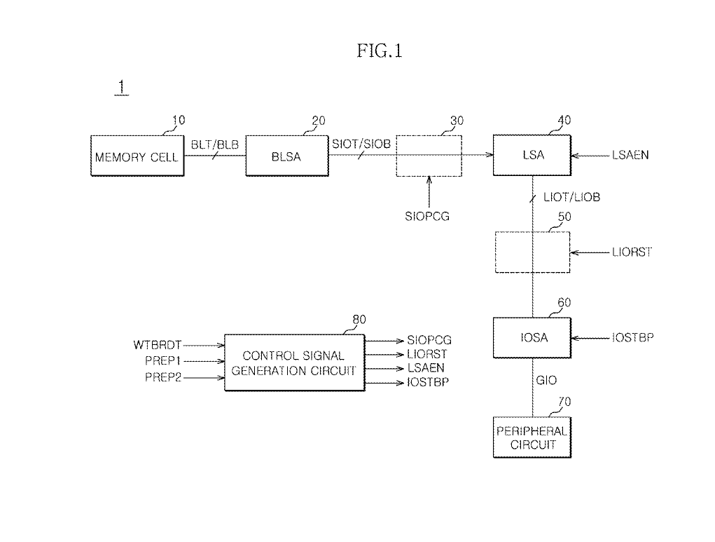

FIG. 1 is a block diagram illustrating a system including a circuit integrated with a semiconductor in accordance with an embodiment. Referring to FIG. 1, the system including a circuit integrated with a semiconductor 1 may include a first data line control unit 30, a first sense amp 40, a second data line control unit 50, a second sense amp 60 and a control signal generation circuit 80.

The first data line control unit 30 is configured to precharge a first data line SIOT/SIOB in response to a first control signal SIOPCG.

The first data line SIOT/SIOB may include a segment input and output line. The first data line SIOT/SIOB may be connected to a bit line sense amp (BLSA) 20

The bit line sense amp (BLSA) 20 may be connected to a memory cell 10 through a bit line (BLT/BLB). [Please see my comments to Para. [0020].]

The second data line control unit 50 is configured to reset, that is, equalize a second data line LIOT/LIOB in response to a second control signal LIORST.

The second data line LIOT/LIOB may include a local input and output line. The first sense amp (LSA) 40 is configured to sense and amplify data of the first data line SIOT/SIOB and transfer the amplified data to the second data line LIOT/LIOB in response to a third control signal LSAEN.

The second sense amp (IOSA) 60 is configured to sense and amplify data of the second data line LIOT/LIOB and transfer the amplified data to a global input and output line GIO in response to a fourth control signal IOSTBP.

The global input and output line GIO may be coupled to a peripheral circuit 70.

The peripheral circuit 70 is configured to output data. The data is transferred through the global input and output line GIO, to outside of the semiconductor integrated circuit 1.

The control signal generation circuit 80 is configured to generate the first to fourth control signals SIOPCG, LIORST, LSAEN and IOSTBP in response to a write status signal WTBRDT and preparatory signals PREP1 and PREP2.

Further, the write status signal WTBRDT may have various distinct logic levels that are different during a write operation and during a read operation.

The preparatory signals PREP1 and PREP2 may be generated by a read command or a write command. Also, the preparatory signals PREP1 and PREP2 may be pulse signals having predetermined pulse durations.

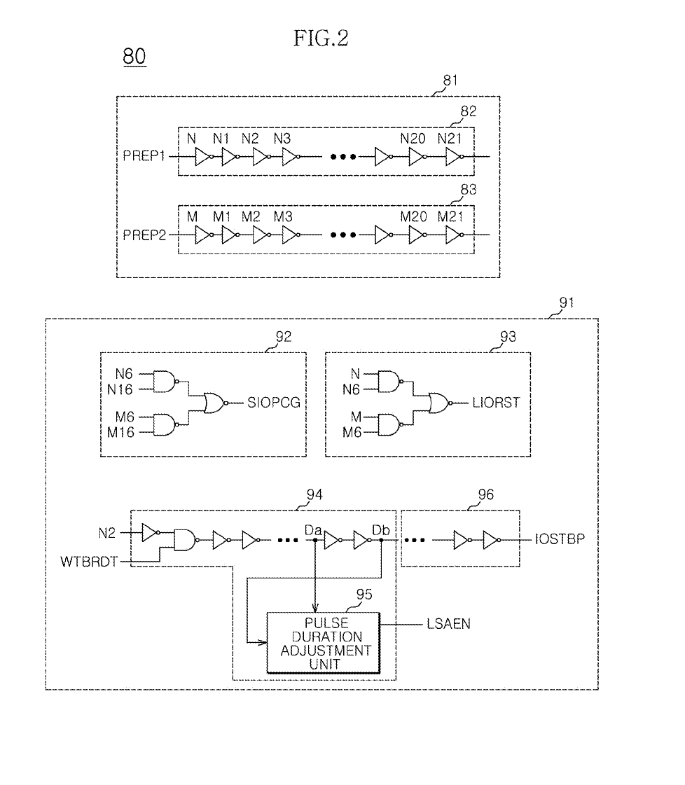

FIG. 2 is a block diagram illustrating the control signal generation unit 80 of the semiconductor integrated circuit 1 shown in FIG. 1.

Referring to FIG. 2, the control signal generation circuit 80 may include a delay signal generation unit 81 and a control signal generation unit 91.

The delay signal generation unit 81 is configured to generate a plurality of delay signals N1 to N21 and M1 to M21 by delaying each of the preparatory signals PREP1 and PREP2.

The delay signal generation unit 81 may include a first delay section 82 and a second delay section 83.

The first delay section 82 is configured to generate the plurality of delay signals N1 to N21 by delaying the preparatory signals PREP1 and PREP2.

The second delay section 83 is configured to generate the plurality of delay signals M1 to M21 by delaying the preparatory signal PREP2.

As shown, each of the first delay section 82 and the second delay section 83 may be implemented with an inverter chain. The control signal generation unit 91 may include a first to a fourth signal generation logics of 92 to 94 and 96, respectively.

The first signal generation logic 92 is configured to generate the first control signal SIOPCG by combining part, for example, the signals N6, N16, M6 and M16 from the pluralities of delay signals N1 to N21 and M1 to M21. The pluralities of delay signals N1 to N21 and M1 to M21 are suitable for a predetermined timing.

The second signal generation logic 93 is configured to generate the second control signal LIORST by combining a part of, for example, the signals N, N6, M and M6 from the larger group of the pluralities of delay signals N1 to N21 and M1 to M21. The pluralities of delay signals N1 to N21 and M1 to M21 are suitable for a predetermined timing.

The third signal generation logic 94 is configured to generate a delay signal, for example, a delay signal Da by combining a source signal, such as, for example N2, and the write status signal WTBRDT and delaying a resultant signal of the combination and output the delay signal as the third control signal LSAEN.

The write status signal WTBRDT may be set at a logic “low” voltage level during the write operation and may be set at a logic “high” voltage level during the read operation.

The third signal generation logic 94 is configured to generate the delay signal Da by combining a source signal and the write status signal WTBRDT to thus delay a resultant signal of the combination. Further, the combination of a source signal and the write status signal WTBRDT may also adjust a pulse duration time of a resultant signal of the delay using another delay signal Db to output the delay signal Da as the third control signal LSAEN.

A source signal may be, for example, the signal N2 of the pluralities of delay signals N1 to N21 and M1 to M21, where the pluralities of delay signals N1 to N21 and M1 to M21 are suitable for a predetermined timing.

The third control signal LSAEN may have a pulse duration time that is relatively longer or shorter than that of a source signal, such as, for example, the signal N2.

The third signal generation logic 94 may further include a plurality of logic gates and a pulse duration adjustment unit 95.

The fourth signal generation logic 96 is configured to output the fourth control signal IOSTBP by delaying the delay signal Db. The delay signal Db is output from the third signal generation logic 94 after a predetermined amount of time.

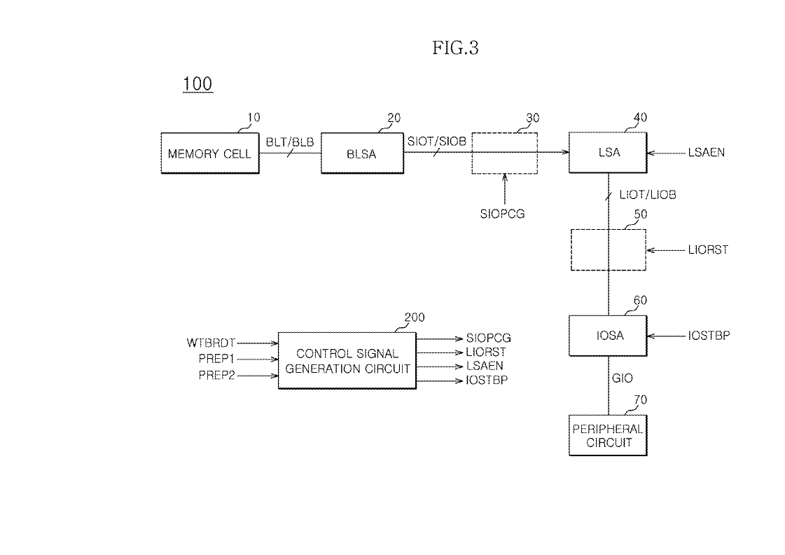

FIG. 3 is a block diagram illustrating a semiconductor integrated circuit in accordance with another embodiment.

Referring to FIG. 3, the semiconductor integrated circuit 100 may include the first data line control unit 30, the first sense amp 40, the second data line control unit 50, the second sense amp 60 and a control signal generation circuit 200.

The first data line control unit 30 is configured to precharge the first data line SIOT/SIOB in response to the first control signal SIOPCG.

The first data line SIOT/SIOB may include a segment input and output line.

The first data line SIOT/SIOB may be coupled to the bit line sense amp (BLSA) 20.

The bit line sense amp (BLSA) 20 may be coupled to the memory cell 10 through a bit line BLT/BLB.

The second data line control unit 50 is configured to reset, that is, equalize the second data line LIOT/LIOB in response to the second control signal LIORST.

The second data line LIOT/LIOB may include a local input and output line.

The first sense amp (LSA) 40 is configured to sense and amplify data of the first data line SIOT/SIOB and to transfer the amplified data to the second data line LIOT/LIOB in response to the third control signal LSAEN.

The second sense amp (IOSA) 60 is configured to sense and amplify data of the second data line LIOT/LIOB and to transfer the amplified data to the global input and output line GIO in response to the fourth control signal IOSTBP.

The global input and output line GIO may be coupled to the peripheral circuit 70.

The peripheral circuit 70 is configured to output data, which is transferred through the global input and output line GIO, to outside of the semiconductor integrated circuit 100.

The control signal generation circuit 200 is configured to generate the first and second control signals SIOPCG and LIORST in response to the preparatory signals PREP1 and PREP2. The control signal generation circuit 200 is also configured to further generate the third and fourth control signals LSAEN and IOSTBP in response to the write status signal WTBRDT.

The write status signal WTBRDT may have various logic voltage levels. The logic voltage levels may differ from during a write operation as opposed to during a read operation. The preparatory signals PREP1 and PREP2 may be generated by the read command or the write command. Further, the preparatory signals PREP1 and PREP2 may be pulse signals having predetermined pulse durations.

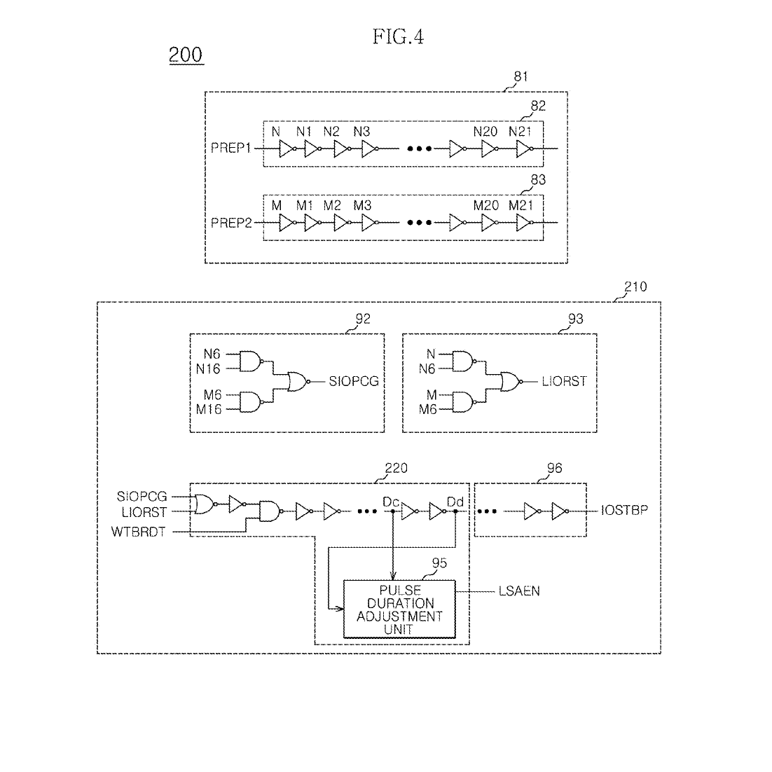

FIG. 4 is a block diagram illustrating a control signal generation unit 200 of the semiconductor integrated circuit 100 shown in FIG. 3.

Referring to FIG. 4, the control signal generation circuit 200 may include the delay signal generation unit 81 and a control signal generation unit 210.

The delay signal generation unit 81 is configured to generate the plurality of delay signals N1 to N21 and M1 to M21 by delaying each of the preparatory signals PREP1 and PREP2

The delay signal generation unit 81 may include the first delay section 82 and the second delay section 83.

The first delay section 82 is configured to generate the plurality of delay signals N1 to N21 by delaying the preparatory signals PREP1 and PREP2.

The second delay section 83 is configured to generate the plurality of delay signals M1 to M21 by delaying the preparatory signal PREP2.

Each of the first delay section 82 and the second delay section 83 may be implemented with an inverter chain. The control signal generation unit 210 may include a first to a fourth signal generation logics 92 to 93, 220 and 96, respectively.

The first signal generation logic 92 is configured to generate the first control signal SIOPCG by combining a part, for example, of the signals N6, N16, M6 and M16 of the pluralities of delay signals N1 to N21 and M1 to M21. The pluralities of delay signals N1 to N21 and M1 to M21 are suitable for a predetermined timing.

The second signal generation logic 93 is configured to generate the second control signal LIORST by combining a part, for example, of the signals N, N6, M and M6 of the plurality of delay signals N1 to N21 and M1 to M21. The pluralities of delay signals N1 to N21 and M1 to M21 are suitable for a predetermined timing.

The third signal generation logic 220 is configured to generate a delay signal, for example, a delay signal Dc by combining the first control signal SIOPCG, the second control signal LIORST and the write status signal WTBRDT. The combination of the signals SIOPCG, LIORST and WTBRDT may then delay a resultant signal of the combination to then output the delay signal Dc as the third control signal LSAEN.

The third signal generation logic 220 is configured to generate the delay signal Dc by performing an OR operation to the first control signal SIOPCG and the second control signal LIORST. The third signal generation logic 220 then performs a NAND operation to the write status signal WTBRDT and a resultant signal of the OR operation to delay a resultant signal of the NAND operation and then output the delay signal Dc as the third control signal LSAEN.

The third signal generation logic 220 is configured to output the third control signal LSAEN by adjusting a pulse duration time of the delay signal Dc.

The third control signal LSAEN may have a pulse duration time relatively longer or shorter than that of the delay signal Dc.

The write status signal WTBRDT may be a logic voltage level of “low” during the write operation and a logic voltage level of “high” during the read operation.

The third signal generation logic 220 may include a plurality of logic gates and the pulse duration adjustment unit 95. The pulse duration adjustment unit 95 is configured to adjust pulse duration of the delay signal Dc using another delay signal Dd.

The fourth signal generation logic 96 is configured to output the fourth control signal IOSTBP by delaying the delay signal Dd. The delay signal Dd is output from the third signal generation logic 220 after a predetermined amount of time.

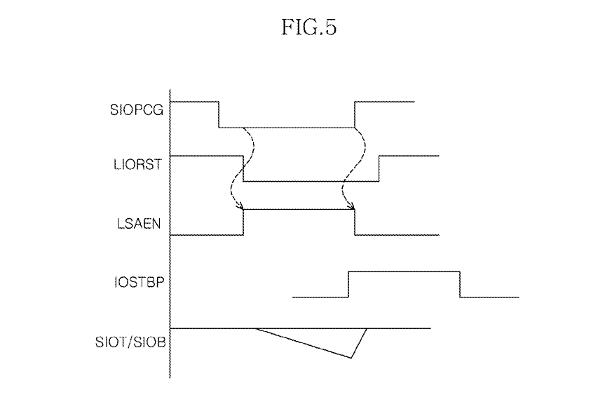

FIG. 5 is a timing diagram illustrating an operation of the semiconductor integrated circuit 100 shown in FIG. 3.

The operation of the semiconductor integrated circuit 100 will be described with reference to FIGS. 3 to 5.

As shown in FIG. 3, data of the memory cell 10 is sensed and amplified through the bit line sense amp 20 and is then transferred to the first data line SIOT/SIOB as the read command is input.

The preparatory signals PREP1 and PREP2 are generated after a predetermined amount of time after input of the read command.

As shown in FIG. 4, the pluralities of delay signals N1 to N21 and M1 to M21 are generated by the delay signal generation unit 81 as the preparatory signals PREP1 and PREP2 are generated.

The first signal generation logic 92 and the second signal generation logic 93 generate the first control signal SIOPCG and the second control signal LIORST by combining a part of the pluralities of delay signals N1 to N21 and M1 to M21. The pluralities of delay signals N1 to N21 and M1 to M21 are suitable for a predetermined timing.

The third signal generation logic 220 activates the third control signal LSAEN to a logic high level at a time when both of the first control signal SIOPCG and the second control signal LIORST have logic low levels.

As shown in FIG. 3, the first sense amp 40 senses and amplifies data of the first data line SIOT/SIOB, in which charge sharing begins. The first sense amp 40 then transfers the amplified data to the second data line LIOT/LIOB as the third control signal LSAEN is activated to have a logic voltage level of “high”.

As shown in FIG. 5, the fourth control signal IOSTBP is activated at a predetermined time after the third control signal LSAEN is activated to have a logic voltage level of “high”.

The third control signal LSAEN is deactivated to have a logic voltage level of “low” as the logic voltage level of the first control signal SIOPCG transitions to a logic voltage level of “high”.

When a pulse duration time of the third control signal LSAEN is longer or shorter than a pulse duration time of the first control signal SIOPCG and a pulse duration time of the second control signal LIORST, a leakage current of the first sense amp 40 may increase or, alternatively, a sensing margin of the second sense amp 60 may not be secured.

In accordance with the embodiments, the third control signal LSAEN is activated and deactivated according to transitions of the first control signal SIOPCG and the second control signal LIORST. Therefore, the third control signal LSAEN may remain connected to the first control signal SIOPCG and the second control signal LIORST to thus experience an expected activation duration time.

As shown in FIG. 3, the second sense amp 60 senses and amplifies data of the second data line LIOT/LIOB and transfers the amplified data to the global input and output line GIO as the fourth control signal IOSTBP is activated.

The peripheral circuit 70 outputs data, which is transferred through the global input and output line GIO, to outside of the semiconductor integrated circuit 100.

While certain embodiments have been described above, it will be understood to those skilled in the art that the embodiments described are by way of example only. Accordingly, the semiconductor integrated circuit described herein should not be interpreted to be limiting as based on the described embodiments.

What is claimed is:

1. A system including a circuit integrated with a semiconductor, comprising:
a first data line;
a second data line;
a first sense amp configured to sense and amplify a data of the first data line and to transfer the amplified data to the second data line in response to a third control signal; and
a control signal generation circuit configured to generate a first control signal for controlling a precharge of the first data line and a second control signal for controlling a reset of the second data line.

2. The system of claim 1 wherein the second control signal controls a reset of the second data line in response to a preparatory signal and the third control signal further wherein the third control is generated in response to both the first control signal and the second control signal.

3. The system of claim 1, wherein the first data line includes a segment input and output line.

4. The system of claim 1, further comprising:
a bit line sense amp connected to the first data line.

5. The system of claim 4, further comprising:
a memory cell connected to the bit line sense amp through a bit line.

6. The system of claim 1, wherein the second data line includes a local input and output line.

7. The system of claim 1, wherein the control signal generation circuit further comprises:
a delay signal generation unit configured to generate a delay signal by delaying the preparatory signals;
a first signal generation logic configured to generate the first control signal by combining a first part of the of delay signal;
a second signal generation logic configured to generate the second control signal by combining a second part of the of delay signal; and
a third signal generation logic configured to generate a delay signal by combining the first control signal and the second control signal and delaying a resultant signal of a combination of the first control signal and the second control signal to output the delay signal as the third control signal.

8. The system of claim 7, wherein the third signal generation logic generates the delay signal by combining the first control signal, the second control signal and a write status signal and delaying a resultant signal of the combination of the first control signal, the second control signal and a write status signal to output the delay signal as the third control signal.

9. The system of claim 7, wherein third signal generation logic generates the delay signal by combining the first control signal, the second control signal and a write status signal, delaying a resultant signal of the combination of the first control signal, the second control signal and a write status signal and adjusting a pulse duration time of a resultant signal of the delay to output the delay signal as the third control signal.

10. The system of claim 2, further comprising:
a second sense amp configured to sense and amplify data of the second data line.

11. The system of claim 10,
wherein the control signal generation circuit generates the first control signal and the second control signal in response to the preparatory signal,
further wherein the control signal generation circuit generates the third control signal and a fourth control signal for controlling the sensing and amplifying operation of the second sense amp in response to the first control signal and the second control signal.

12. The system of claim 11, wherein the control signal generation circuit further comprises:
a delay signal generation unit configured to generate a delay signal by delaying the preparatory signal;
a first signal generation logic configured to generate the first control signal by combining a part of the delay signal;
a second signal generation logic configured to generate the second control signal by combining another part of the f delay signal;
a third signal generation logic configured to generate a delay signal by combining the first control signal and the second control signal and delaying a resultant signal of the combination of the first control signal and the second control signal and to output the delay signal as the third control signal; and
a fourth signal generation logic configured to output the fourth control signal by delaying the delay signal output from the third signal generation logic by a predetermined amount of time.

13. A semiconductor integrated circuit comprising:
a first data line control unit configured to precharge a first data line in response to a first control signal;
a second data line control unit configured to precharge a second data line in response to a second control signal;
a sense amp configured to sense and amplify a data of the first data line and transfer the amplified data to the second data line in response to a third control signal; and
a control signal generation circuit configured to generate the first control signal and the second control signal in response to a preparatory signal, which are generated according to a read command, and generate the third control signal in response to the first control signal and the second control signal.

14. The semiconductor integrated circuit of claim 12, wherein the first data line includes a segment input and output line.

15. The semiconductor integrated circuit of claim 12, wherein the second data line includes a local input and output line.

16. The semiconductor integrated circuit of claim 12, wherein the control signal generation circuit further comprises:
a delay signal generation unit configured to generate a delay signal by delaying the preparatory signal;
a first signal generation logic configured to generate the first control signal by combining a part of the delay signal;
a second signal generation logic configured to generate the second control signal by combining another part of the delay signal; and
a third signal generation logic configured to generate a delay signal by combining the first control signal and the second control signal and delaying a resultant signal of the combination of the the first control signal and the second control signal and to output the delay signal as the third control signal.

17. The semiconductor integrated circuit of claim 16, wherein the third signal generation logic generates the delay signal by combining the first control signal, the second control signal and a write status signal and by delaying a resultant signal of the combination to output the delay signal as the third control signal.

18. The semiconductor integrated circuit of claim 16, wherein the third signal generation logic generates the delay signal by combining the first control signal, the second control signal and a write status signal and by delaying a resultant signal of the combination of the first control signal, the second control signal and the write status signal and by adjusting a pulse duration time of a resultant signal of the delay and to output the delay signal as the third control signal.
